(19) United States
(12) Patent Application Publication
(10) Pub. No.: US 2014/0214362 A1
(43) Pub. Date: Jul. 31, 2014

(54) METHOD AND SYSTEM OF DETECTING FLICKERING FREQUENCY OF AMBIENT LIGHT SOURCE

(71) Applicant: Lextar Electronics Corporation, Hsinchu Science Park (TW)

(72) Inventors: Yuan-Ching CHEN, Kaohsiung City (TW); Chun-Kuang CHEN, Taipei City (TW)

(73) Assignee: Lextar Electronics Corporation, Hsinchu Science Park (TW)

(21) Appl. No.: 14/055,289

(22) Filed: Oct. 16, 2013

(30) Foreign Application Priority Data
Jan. 28, 2013 (TW) 102103151

(51) Int. Cl. G01R 31/44

(52) U.S. Cl. CPC G01R 31/44
USPC 702/176

(57) ABSTRACT

A method of detecting a flickering frequency of an ambient light source includes the following steps. First, a light intensity of the light source is sensed in a predetermined time period according to a sampling frequency to obtain a plurality of sample values. Then, the sample values are calculated to obtain a median value. Next, the sample values are binarized according to a result of a comparison between the sample values and the median value to obtain a first sequence. The first sequence is differentiated to obtain a second sequence, and the second sequence includes numbers −1, 0, and 1. Then, a distance between the same numbers in the second sequence is calculated, and the sampling frequency is divided by the distance to obtain the flickering frequency of the ambient light source. A system of detecting a flickering frequency of an ambient light source is also disclosed herein.

### RELATED APPLICATIONS

This application claims priority to Taiwan Application Serial Number 102103151, filed Jan. 28, 2013, which is herein incorporated by reference.

### BACKGROUND

1. Field of Invention

The invention relates to a detecting method and a detecting system. More particularly, the invention relates to a method and a system of detecting a flickering frequency of an ambient light source.

2. Description of Related Art

A light emitting diode (LED) has a small size and long lifetime, saves power and is difficult to be damaged. Therefore, the LED has gradually replaced a fluorescent tube and an incandescent bulb and widely been used in illumination recently.

The brightness of a LED lamp is varied by using a pulse-width modulation (PWM) method or a tri-electrode AC switch (TRIAC) dimmer.

The PWM method switches on/off a light source of the LED quickly to make the light source as a pulse and then adjusts a switching on/off time proportion to change an output brightness of the LED. Therefore, if a switching frequency is not quick enough (e.g., below 120 Hz) or the switching on/off time proportion is too small (for example the pulse formed by the light emitted from the LED has a short time at a high potential level and a long time at a low potential level) to cause an output current of a LED driver to be switched off before the output current becomes stable, people's eyes will feel a flicker.

The TRIAC dimmer can be a traditional incandescent lamp dimmer. At the time of dimming, if a current flowing through the TRIAC dimmer is smaller than an operating current of the dimmer, the LED lamp will be switched repeatedly to make people's eyes feel a flicker.

From the above-mentioned, it can be known that a dimming frequency and a light intensity of the LED lamp will influence whether people's eyes feel a flicker of the ambient light source. Generally, when the dimming frequency is smaller than 120 Hz, it will make people's eyes feel a flicker, and a weak light is easier to make people's eyes feel a flicker than a strong light.

Currently wireless handheld devices all have inbuilt light sensing units which can adjust a backlight brightness of a screen of the wireless handheld device automatically by sensing the variation of light intensity of the ambient light source (for example when the ambient light source is brighter, the backlight brightness of the screen is weaker; and when the ambient light source is darker, the backlight brightness of the screen is stronger). However, the wireless handheld device cannot sense a flickering frequency of the ambient light source.

For this reason, it is necessary to use the light sensing unit to detect the flickering frequency of the ambient light source to evaluate a light environment.

### SUMMARY

An aspect of the invention provides a method of detecting a flickering frequency of an ambient light source, which senses the ambient light source at first and then uses a numeric calculation to obtain the flickering frequency of the light source.

An embodiment of the invention relates to a method of detecting a flickering frequency of an ambient light source which includes the following steps. First, a light intensity of a light source is sensed in a predetermined time period according to a sampling frequency to obtain a plurality of sample values. Then, the above-mentioned sample values are calculated to obtain a median value. Next, a comparison is made between the sample values and the median value, and the sample values are binarized according to a result of the comparison to obtain a first sequence. The first sequence is differentiated to obtain a second sequence, in which the second sequence includes numbers −1, 0, and 1. Then, a distance N between the same numbers in the second sequence is calculated, and the sampling frequency is divided by the distance N to obtain the flickering frequency of the light source, in which the distance N is a positive integer greater than 1.

Another embodiment of the invention relates to a method of detecting a flickering frequency of an ambient light source, in which the sampling frequency is greater than a predetermined frequency.

A further embodiment of the invention relates to a method of detecting a flickering frequency of an ambient light source, in which the above-mentioned median value is a sum of (1-k) times of the minimum sample value and k times of the maximum sample value, with 0<k <1.

Yet a further embodiment of the invention relates to a method of detecting a flickering frequency of an ambient light source, in which the step of calculating the distance N between the same numbers in the second sequence includes: calculating the distance N between two numbers 1 or two numbers −1 in the second sequence.

Still yet a further embodiment of the invention relates to a method of detecting a flickering frequency of an ambient light source, in which the distance N between two numbers 1 in the second sequence has a first numeric value and the distance N between two numbers −1 in the second sequence has a second numeric value. The flickering frequency of the light source is between the sampling frequency divided by the first numeric value and the sampling frequency divided by the second numeric value.

Another embodiment of the invention relates to a method of detecting a flickering frequency of an ambient light source, in which the step of sensing the light intensity of the light source is achieved by a light sensing unit.

Another aspect of the invention provides a system of detecting a flickering frequency of an ambient light source which detects and calculates the flickering frequency of the ambient light source so as to adjust the flickering frequency of the ambient light source.

An embodiment of the invention relates to a system of detecting a flickering frequency of an ambient light source which includes at least one light-emitting device, a light sensing unit and a processing unit. The at least one light-emitting device is configured for providing at least one light source. The light sensing unit is configured for sensing the light intensity of the light source according to the sampling frequency to obtain a plurality of sample values. The processing unit calculates the above-mentioned sample values to obtain a median value, makes a comparison between the sample values and the median value, and binarizes the sample values according to a result of the comparison to obtain a first sequence. Then the processing unit differentiates the first sequence to obtain a second sequence. The processing unit calculates a distance N between the same numbers in the second sequence, and divides the sampling frequency by the distance N to obtain the flickering frequency of the light source, in which the distance N is a positive integer greater than 1.

Another embodiment of the invention relates to a system of detecting a flickering frequency of an ambient light source, in which the light sensing unit and the processing unit are integrated into a wireless handheld device.

A further embodiment of the invention relates to a system of detecting a flickering frequency of an ambient light source, in which the wireless handheld device transmits a dimming signal to the light-emitting device.

Yet a further embodiment of the invention relates to a system of detecting a flickering frequency of an ambient light source, which further includes a network and an external wireless module, in which the light sensing unit and the processing unit are integrated into the wireless handheld device.

Still yet a further embodiment of the invention relates to a system of detecting a flickering frequency of an ambient light source, in which the wireless handheld device translates the dimming control signal through the external wireless module and the translated dimming control signal is transmitted to the light-emitting device through the network.

Another embodiment of the invention relates to a system of detecting a flickering frequency of an ambient light source, in which the processing unit is integrated into the wireless handheld device and the light sensing unit is positioned externally to the wireless handheld device. The wireless handheld device is further configured for communicating with the light sensing unit wirelessly and transmitting the sample values received from the light sensing unit to the processing unit.

A further embodiment of the invention relates to a system of detecting a flickering frequency of an ambient light source, in which the wireless handheld device transmits the dimming signal to the light-emitting device.

Yet a further embodiment of the invention relates to a system of detecting a flickering frequency of an ambient light source, which further includes the network and the external wireless module. The processing unit is integrated into the wireless handheld device and the light sensing unit is positioned externally to the wireless handheld device and uploads these sample values to the network and the external wireless module downloads these sample values from the network and transmits these sample values to the processing unit.

Still yet a further embodiment of the invention relates to a system of detecting a flickering frequency of an ambient light source, in which the wireless handheld device translates the dimming control signal through the external wireless module and the translated dimming control signal is transmitted to the light-emitting device through the network.

Another embodiment of the invention relates to a system of detecting a flickering frequency of an ambient light source, in which the light-emitting device includes a first wireless module.

A further embodiment of the invention relates to a system of detecting a flickering frequency of an ambient light source, in which the light sensing unit includes a second wireless module.

Yet a further embodiment of the invention relates to a system of detecting a flickering frequency of an ambient light source, in which the above-mentioned light source includes at least one LED.

Still yet a further embodiment of the invention relates to a system of detecting a flickering frequency of an ambient light source, in which a sampling frequency Fₛ is greater than a predetermined frequency.

Another embodiment of the invention relates to a system of detecting a flickering frequency of an ambient light source, in which the above-mentioned median value is a sum of (1-k) times of the minimum sample value and k times of the maximum sample value, with 0<k <1.

A further embodiment of the invention relates to a system of detecting a flickering frequency of an ambient light source, in which the distance N is a distance between two numbers 1 or two numbers −1 in the second sequence.

Yet a further embodiment of the invention relates to a system of detecting a flickering frequency of an ambient light source, in which the distance N between two numbers 1 in the second sequence has a first numeric value and the distance N between two numbers −1 in the second sequence has a second numeric value. The flickering frequency F_{f} of the light source is between the sampling frequency Fₛ divided by the first numeric value and the sampling frequency Fₛ divided by the second numeric value.

### BRIEF DESCRIPTION OF THE DRAWINGS

FIG. 1 illustrates a flow chart of a method of detecting a flickering frequency of an ambient light source according to an embodiment of the invention;

FIG. 2 illustrates an example of a method of detecting a flickering frequency of an ambient light source according to another embodiment of the invention;

FIG. 3 illustrates a system of detecting a flickering frequency of an ambient light source according to an embodiment of the invention;

FIG. 4 illustrates a system of detecting a flickering frequency of an ambient light source according to another embodiment of the invention;

FIG. 5 illustrates a system of detecting a flickering frequency of an ambient light source according to a further embodiment of the invention; and

FIG. 6 illustrates a system of detecting a flickering frequency of an ambient light source according to yet a further embodiment of the invention.

### DETAILED DESCRIPTION

The invention will be described in details in the following embodiments with reference to the accompanying drawings, but these embodiments are not intended to limit the scope of the invention. The description of structure operation does not mean to limit its implementation order. Any device with equivalent functions that is produced from a structure formed by recombination of elements shall fall within the scope of the invention. Moreover, the accompanying drawings are only illustrative and are not made according to the original size.

For the terms “about”, “approximately” or “roughly”, they usually refer to the error or range of the quantity in 20%, preferably in 10%, and more preferably in 5%. If no clear description is provided herein, the numeric values mentioned are all regarded as approximate values, i.e., as the error or range represented by “about”, “approximately” or “roughly”.

The following embodiments of the invention disclose a method of detecting a flickering frequency of an ambient light source. The method senses the ambient light source and then a numeric calculation is performed for the obtained sample values after sensing to obtain the flickering frequency of the light source.

For example, a light sensing unit in a wireless handheld device can be configured for sensing the ambient light source and then a processing unit in the wireless handheld device is configured for performing the numeric calculation to calculate the flickering frequency of the light source.

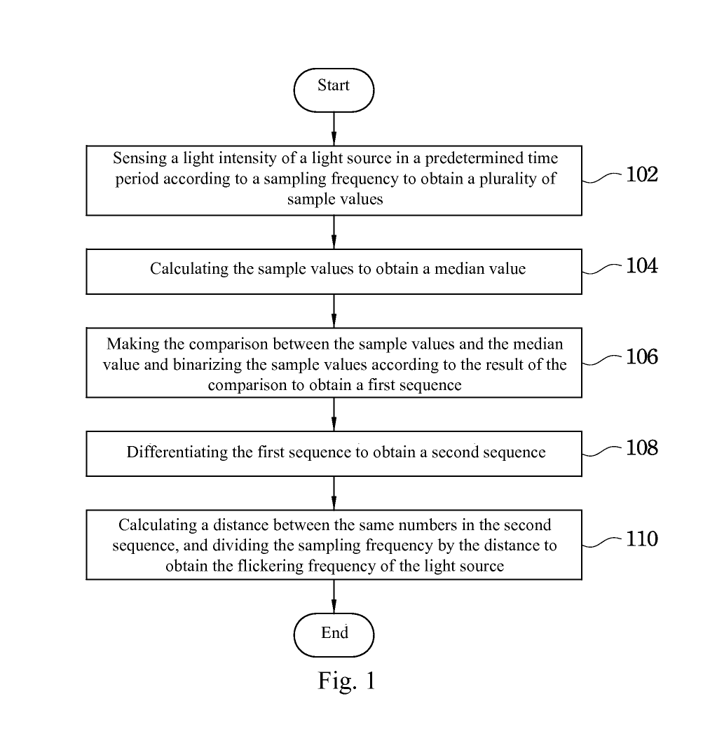

FIG. 1 illustrates a flow chart of a method of detecting a flickering frequency of an ambient light source according to an embodiment of the invention and the detecting method in the embodiment includes the following steps. First, a light intensity of a light source is sensed in a predetermined time period according to a sampling frequency Fₛ for some time to obtain a plurality of sample values An (step 102). In an embodiment, the sampling frequency Fₛ is greater than a predetermined frequency F_{fs} and the predetermined frequency F_{fs} is a frequency of a pulse with a minimum width which is modulated by a pulse-width modulation (PWM) method.

In practice, the above-mentioned step of sensing the light intensity of the light source can be achieved by the light sensing unit (such as an image sensor of a charge coupled device (CCD) camera or a CMOS camera), but not limited to this.

Then, after step 102, the aforesaid obtained sample values An are calculated to obtain a median value A_{TH} (step 104). The calculation method of the median value A_{TH} can be A_{TH}=Amin+k (Amax−Amin), in which Amin is a minimum sampling value and Amax is a maximum sampling value, and 0<k <1. That is, the median value A_{TH} is a sum of (1-k) times of the minimum sample value and k times of the maximum sample value.

Next, a comparison is made between the aforesaid sample values An and the median value A_{TH} and the sample values An are binarized according to a result of the comparison to obtain a first sequence Wn1 (step 106). At step 106, if the sample values An are greater than the median value A_{TH}, the sample values An are binarized as number 1; and on the contrary, if the sample values An are smaller than the median value A_{TH}, the sample values An are binarized as number 0.

Afterwards, the first sequence Wn1 is differentiated to obtain a second sequence Wn2, in which the second sequence Wn2 includes numbers −1, 0, and 1 (step 108). At step 108, the difference calculation for the first sequence Wn1 may be a forward difference or a backward difference. The sequence obtained after the difference calculation is the second sequence Wn2. For the forward difference, for example, the numeric values obtained after the binarization calculation include Z1, Z2, . . . , Zn, Zn+1 and so on, and the numeric values obtained after the forward difference calculation are Wn=Zn+1−Zn; and on the contrary, the numeric values obtained after the backward difference calculation are Wn=Zn−Zn+1, and as described above, when An >A_{TH}, Zn=1, while when An <A_{TH}, Zn=0.

Then, the distance N between the same numbers in the second sequence Wn2 is calculated, and the sampling frequency Fₛ is divided by the distance N to obtain the flickering frequency F_{f} of the light source, in which the distance N is a positive integer greater than 1 (step 110).

It should be illustrated that, the aforesaid distance N between the same numbers refers to the distance of the numbers, i.e., the interval number between the same numbers, rather than the length distance. For example, the distance N between two adjacent numbers in the sequence is 1 (the interval number being 1), while if another number is inserted between two numbers in the sequence, the distance N is 2 (the interval number being 2). The rest can be done in the same manner.

In another embodiment, the aforesaid step 110 of calculating the distance N between the same numbers in the second sequence Wn2 can further include: calculating the distance N between two numbers 1 or two numbers −1 in the second sequence Wn2. If the distance N between two numbers 1 is different from that between two numbers −1, for example, the distance N between two numbers 1 has a first numeric value N1 while the distance N between two numbers −1 has a second numeric value N2, the flickering frequency F_{f} of the light source is between the sampling frequency Fₛ divided by the first numeric value N1 and the sampling frequency Fₛ divided by the second numeric value N2; that is, Fₛ/N2 <F_{f} <Fₛ/N1, in which N1 <N2, and on the contrary, if N2 <N1, then Fₛ/N1 <F_{f} <Fₛ/N2.

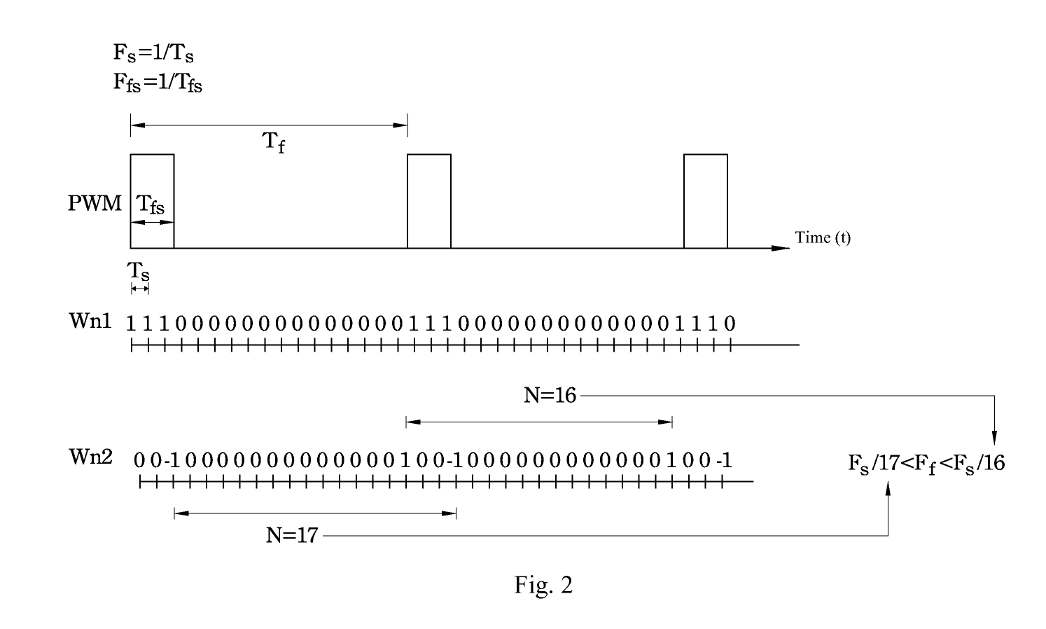

For the purpose of convenience for description, references are made to both of FIG. 1 and FIG. 2. FIG. 2 illustrates an example of a method of detecting a flickering frequency of an ambient light source according to another embodiment of the invention. As shown in FIG. 2, when the PWM method is used for the ambient light source as the dimming method, the ambient light source is sensed and the flickering frequency of the light source is calculated.

For example, a sampling period Tₛ can be configured for sensing the light intensity of the ambient light source to obtain multiple sample values, in which the sampling period Tₛ is smaller than the minimum dimming pulse width T_{fs} of the pulse-width modulation signal PWM. That is, the sampling frequency Fₛ (Fₛ=1/Tₛ) is greater than the dimming frequency F_{fs} (F_{fs}=1/T_{fs}) at this time.

Through step 102, step 104 and step 106 in FIG. 1, after sensing the light intensity of the light source to obtain the plurality of sample values An, calculating the sample values An to obtain the median value A_{TH}, making a comparison between the sample values An and the median value A_{TH} and binarizing the sample values An, the first sequence Wn1 can be obtained.

An example of the first sequence Wn1 is shown in FIG. 2. The second sequence Wn2 which is obtained after differentiating (the forward differentiation in this example) the first sequence Wn1 (as step 108 shown in FIG. 1) is also shown in FIG. 2. From the figure, it can be seen that the second sequence Wn2 includes numbers −1, 0 and 1.

Then, according to step 110 in FIG. 1, after calculating the distance N between the same numbers in the second sequence Wn2, the flickering frequency F_{f} of the light source is obtained by calculating. In the example of FIG. 2, the distance N between two numbers 1 in the second sequence Wn2 is 16 (i.e., the interval number being 16) while the distance N between two numbers −1 is 17 (i.e., the interval number being 17). Therefore, the flickering frequency F_{f} of the ambient light source is between the sampling frequency Fₛ divided by 17 and the sampling frequency Fₛ divided by 16, (i.e., Fₛ/17<F_{f}<Fₛ/16), in which the flickering frequency F_{f} is the reciprocal of the flickering period T_{f} (F_{f}=1/T_{f}).

By referring to FIG. 1 and FIG. 2 at the same time, it can be known clearly that how the method of detecting the flickering frequency of the ambient light source disclosed in FIG. 1 is used in the actual example (as show in FIG. 2) to obtain the flickering frequency of the light source.

A further embodiment of the invention discloses a system of detecting a flickering frequency of an ambient light source which includes at least one light-emitting device, a light sensing unit and a processing unit. The light-emitting device is configured for providing at least one light source. The light source can include a LED. The light sensing unit is configured for sensing the light intensity of the light source according to the sampling frequency Fₛ to obtain a plurality of sample values An. The processing unit calculates the sample values An to obtain the median value A_{TH}, and then makes a comparison between the sample values An and the median value A_{TH} and binarizes the sample values An according to a result of the comparison to obtain the first sequence Wn1. Next, the first sequence Wn1 is differentiated to obtain the second sequence Wn2. The processing unit calculates the distance N (i.e., the interval number N) between the same numbers (e.g., numbers 1 or −1) in the second sequence Wn2, and divides the sampling frequency Fₛ by the distance N to obtain the flickering frequency F_{f} of the light source, in which N is a positive integer greater than 1.

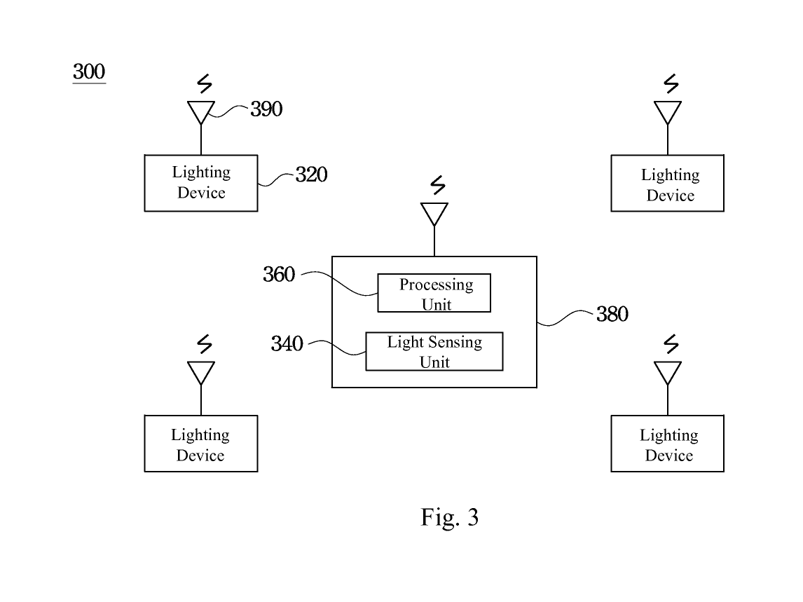

FIG. 3 illustrates a system of detecting a flickering frequency of an ambient light source according to an embodiment of the invention. The detecting system 300 includes a light-emitting device 320, a light sensing unit 340, a processing unit 360 and a wireless handheld device 380. The light-emitting device 320 includes a first wireless module 390, and the light sensing unit 340 and the processing unit 360 are integrated into the wireless handheld device 380.

The light sensing unit 340 in the wireless handheld device 380 can sense the light intensity of the ambient light source provided by the light-emitting device 320 to obtain a plurality of sample values An and then the processing unit 360 in the wireless handheld device 380 calculates the sample values An as above to obtain the flickering frequency F_{f} of the light source.

In addition, if the light-emitting device 320 is a light-emitting device with a dimming function, the light-emitting device 320 can communicate with the wireless handheld device 380 wirelessly through the first wireless module 390 so that the wireless handheld device 380 can further transmit the dimming signal to the light-emitting device 320 according to the flickering frequency F_{f} obtained by the calculation of the processing unit 360 in the wireless handheld device 380 to change the characteristic of an output light source of the light-emitting device 320. Therefore, after reading the flickering frequency F_{f} of the ambient light source, users can further determine and control the flickering frequency F_{f} of the light-emitting device 320 wirelessly through a control interface on the wireless handheld device 380 and by any form of wireless module (e.g., bluetooth or WiFi, etc.) in the wireless handheld device 380 so as to change the characteristic of the output light source of the light-emitting device 320, thereby reaching an effect of adjusting the flickering frequency F_{f} of the light source.

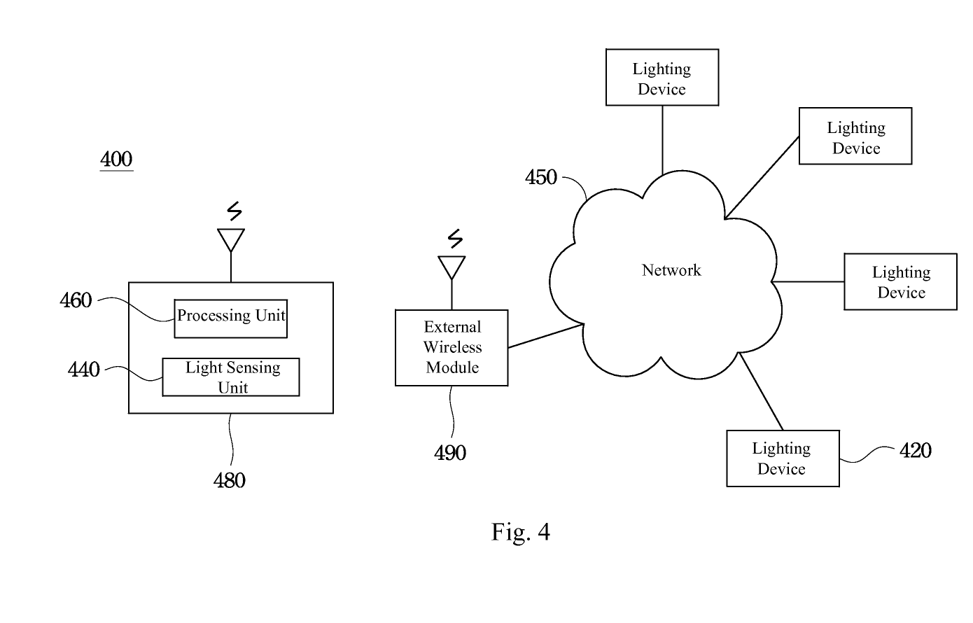

FIG. 4 illustrates a system of detecting a flickering frequency of an ambient light source according to another embodiment of the invention. The detecting system 400 is similar to the detecting system 300 and includes a light-emitting device 420, a light sensing unit 440, a processing unit 460 and a wireless handheld device 480. The light sensing unit 440 and the processing unit 460 are integrated into the wireless handheld device 480. In addition to this, the detecting system 400 further includes a network 450 and an external wireless module 490.

As shown in FIG. 4, the light sensing unit 440 in the wireless handheld device 480 can sense the light intensity of the ambient light source to obtain a plurality of sample values An and then the processing unit 460 in the wireless handheld device 480 calculates the sample values An as above to obtain the flickering frequency F_{f} of the light source.

In addition, if the light-emitting device 420 is a light-emitting device with the dimming function, by the wireless communication between the external wireless module 490 and the wireless handheld device 480, the wireless handheld device 480 can further translate a dimming control signal through the external wireless module 490; that is, the wireless handheld device 480 transmits the dimming control signal to the external wireless module 490 to make the external wireless module 490 translate the dimming control signal. Since the light-emitting device 420 and the external wireless module 490 are connected to each other through the network 450, the translated dimming control signal is transmitted to the light-emitting device 420 through the network 450 to adjust and control the light-emitting device 420.

That is, after reading the flickering frequency F_{f} of the ambient light source, users can further communicate with the external wireless module 490 wirelessly through the control interface on the wireless handheld device 480 and by any form of wireless module (e.g., bluetooth or WiFi, etc.) in the wireless handheld device 480 so that the external wireless module 490 transmits the translated dimming control signal to the light-emitting device 420 through the network 450 to determine and control the flickering frequency F_{f} of the light-emitting device 420 wirelessly, thereby reaching the effect of adjusting the flickering frequency F_{f} of the light source by controlling the flickering frequency F_{f} of the light-emitting device 420 wirelessly.

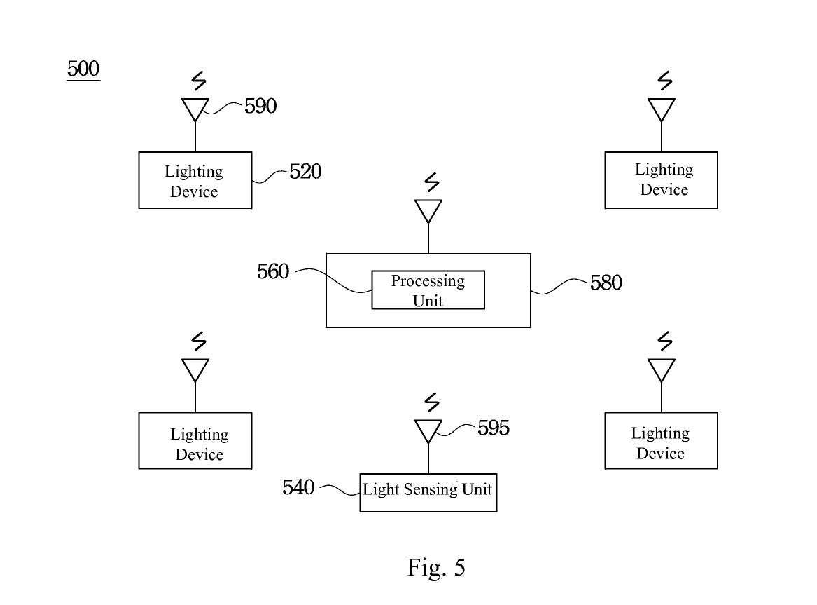

FIG. 5 illustrates a system of detecting a flickering frequency of an ambient light source according to a further embodiment of the invention. The detecting system 500 is similar to the detecting system 300 and includes a light-emitting device 520, a light sensing unit 540, a processing unit 560 and a wireless handheld device 580. The light-emitting device 520 includes a first wireless module 590 and the light sensing unit 540 includes a second wireless module 595. The processing unit 560 is integrated into the wireless handheld device 580 while the light sensing unit 540 is positioned externally to the wireless handheld device 580.

The light sensing unit 540 can sense the light intensity of the ambient light source provided by the light-emitting device 520 to obtain a plurality of sample values An. Then, the wireless handheld device 580 can receive the sample values An sensed by the light sensing unit 540 through the second wireless module 595 and then transmits the sample values An to the processing Unit 560 for the aforesaid calculation to obtain the flickering frequency F_{f} of the light source.

In addition, if the light-emitting device 520 is a light-emitting device with the dimming function, the light sensing unit 540 can communicate with the first wireless module 590 in the light-emitting device 520 wirelessly through the second wireless module 595 so that the wireless handheld device 580 can further transmit the dimming signal to the light-emitting device 520 according to the flickering frequency F_{f} obtained by the calculation of the processing unit 560 in the wireless handheld device 580. In such a way, after reading the flickering frequency F_{f} of the ambient light source, users can further determine and control the flickering frequency F_{f} of the light-emitting device 520 wirelessly through the control interface on the wireless handheld device 580 and by any form of wireless module (e.g., bluetooth or WiFi) in the wireless handheld device 580 so as to change the characteristic of the output light source of the light-emitting device 520, thereby reaching the effect of adjusting the flickering frequency F_{f} of the light source.

It should be illustrated that, the light sensing unit 540 positioned externally to the wireless handheld device 580 can include any light sensing device which can be plugged in externally, for example, an image sensor of a light sensing element (e.g., a charge coupled device (CCD) camera or a CMOS camera).

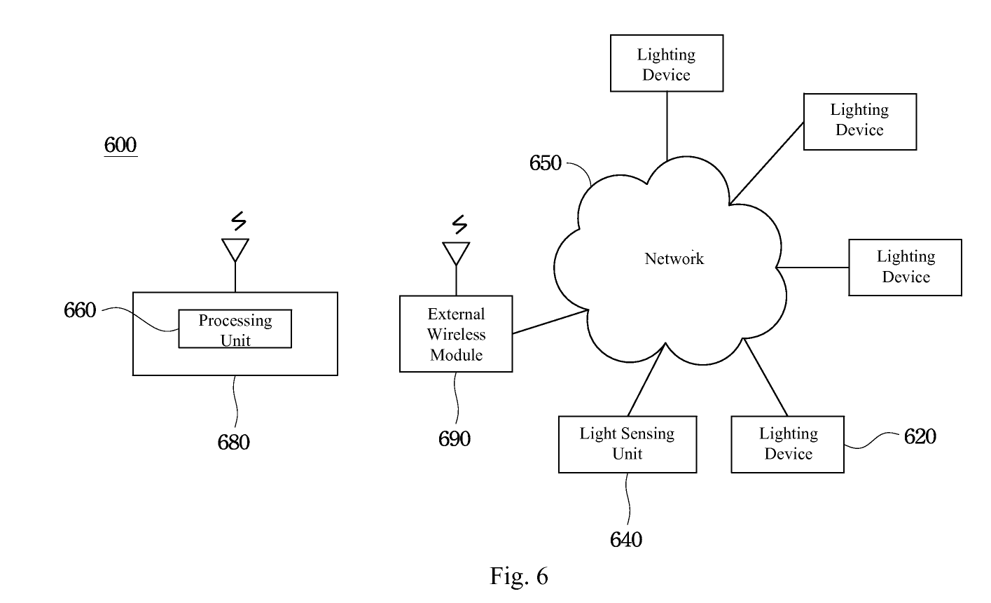

FIG. 6 illustrates a system of detecting a flickering frequency of an ambient light source according to yet a further embodiment of the invention. The detecting system 600 is similar to the detecting system 300 and includes a light-emitting device 620, a light sensing unit 640, a processing unit 660 and a wireless handheld device 680. The processing unit 660 is integrated into the wireless handheld device 680, and the light sensing unit 640 is positioned in the wireless handheld device 680. In addition to this, the detecting system 600 further includes a network 650 and an external wireless module 690.

Since the light-emitting device 620, the light sensing unit 640 and the external wireless module 690 are connected to each other through the network 650, after the light sensing unit 640 uploads the sample values An to the network 650, the external wireless module 690 downloads the sample values An through the network 650.

Through the wireless communication between the external wireless module 690 and the wireless handheld device 680, the external wireless module 690 transmits the downloaded sample values An to the processing unit 660 in the wireless handheld device 680 and then the processing unit 660 calculates the sample values An as above to obtain the flickering frequency F_{f} of the light source.

In addition, if the light-emitting device 620 is a light-emitting device with the dimming function, the wireless handheld device 680 can further translate a dimming control signal through the external wireless module 690; that is, the wireless handheld device 680 transmits the dimming control signal to the external wireless module 690 to make the external wireless module 690 translate the dimming control signal and then the translated dimming control signal is transmitted to the light-emitting device 620 through the network 650 to adjust and control the light-emitting device 620.

That is, after reading the flickering frequency F_{f} of the ambient light source, users can further communicate with the external wireless module 690 wirelessly through the control interface on the wireless handheld device 680 and by any form of wireless module (e.g., bluetooth or WiFi) in the wireless handheld device 680 so that the external wireless module 690 transmits the translated dimming control signal to the light-emitting device 620 to determine and control the flickering frequency F_{f} of the light-emitting device 620 wirelessly, thereby reaching the effect of adjusting the flickering frequency F_{f} of the light source by controlling the flickering frequency F_{f} of the light-emitting device 620 wirelessly.

The invention uses a simple numeric calculation method to make a general wireless handheld device detect the flickering frequency of the ambient light source. Moreover, if the LED lamp has the dimming function, the wireless handheld device also can adjust the flickering frequency of the ambient light source after detecting the flickering frequency of the ambient light source, so to make people's eyes no longer feel uncomfortable due to the flicker of the ambient light source, and thus the problem of the flicker of the ambient light source is solved successfully.

Although the invention has been disclosed with reference to the above embodiments, these embodiments are not intended to limit the invention. Those of skills in the art can make various modifications and changes, without departing from the spirit and scope of the invention. Therefore, the scope of the invention should be defined by the appended claims.

What is claimed is:

1. A method of detecting a flickering frequency of an ambient light source, comprising:
sensing a light intensity of a light source in a predetermined time period according to a sampling frequency to obtain a plurality of sample values;
calculating the sample values to obtain a median value;
making a comparison between the sample values and the median value and binarizing the sample values according to a result of the comparison to obtain a first sequence;
differentiating the first sequence to obtain a second sequence, wherein the second sequence comprises numbers −1, 0 and 1; and
calculating a distance N between the same numbers in the second sequence, and dividing the sampling frequency by the distance N to obtain the flickering frequency of the light source, wherein the distance N is a positive integer greater than 1.

2. The method of claim 1, wherein the sampling frequency is greater than a predetermined frequency.

3. The method of claim 1, wherein the median value is a sum of (1-k) times of a minimum sample value and k times of a maximum sample value, wherein 0<k <1.

4. The method of claim 1, wherein the step of calculating the distance N between the same numbers in the second sequence comprises:
calculating the distance N between two numbers 1 or two numbers −1 in the second sequence.

5. The method of claim 4, wherein the distance N between two numbers 1 in the second sequence has a first numeric value, the distance N between two numbers −1 in the second sequence has a second numeric value and the flickering frequency of the light source is between the sampling frequency divided by the first numeric value and the sampling frequency divided by the second numeric value.

6. The method of claim 1, wherein the step of sensing the light intensity of the light source is achieved by a light sensing unit.

7. A system of detecting a flickering frequency of an ambient light source, comprising:
at least one light-emitting device, configured for providing at least one light source;
a light sensing unit, configured for sensing the light intensity of the light source according to a sampling frequency to obtain a plurality of sample values; and
a processing unit, wherein the processing unit calculates the sample values to obtain a median value, makes a comparison between the sample values and the median value, binarizes the sample values according to a result of the comparison to obtain a first sequence and differentiates the first sequence to obtain a second sequence, wherein the processing unit calculates a distance N between the same numbers in the second sequence and divides the sampling frequency by the distance N to obtain the flickering frequency of the light source and the distance N is a positive integer greater than 1.

8. The detecting system of claim 7, wherein the light sensing unit and the processing unit are integrated into a wireless handheld device.

9. The detecting system of claim 8, wherein the wireless handheld device transmits a dimming signal to the light-emitting device.

10. The detecting system of claim 7, further comprising a network and an external wireless module, wherein the light sensing unit and the processing unit are integrated into a wireless handheld device.

11. The detecting system of claim 10, wherein the wireless handheld device translates a dimming control signal through the external wireless module and the translated dimming control signal is transmitted to the light-emitting device through the network.

12. The detecting system of claim 7, wherein the processing unit is integrated into a wireless handheld device, the light sensing unit is positioned externally to the wireless handheld device, the wireless handheld device is further configured for communicating with the light sensing unit wirelessly and transmitting the sample values received from the light sensing unit to the processing unit.

13. The detecting system of claim 12, wherein the wireless handheld device transmits a dimming signal to the light-emitting device.

14. The detecting system of claim 7, further comprising a network and an external wireless module, wherein the processing unit is integrated into a wireless handheld device, the light sensing unit is positioned externally to the wireless handheld device and uploads the sample values to the network, and the external wireless module downloads the sample values from the network and transmits them to the processing unit.

15. The detecting system of claim 14, wherein the wireless handheld device translates a dimming control signal through the external wireless module and the translated dimming control signal is transmitted to the light-emitting device through the network.

16. The detecting system of claim 8, wherein the light-emitting device comprises a first wireless module.

17. The detecting system of claim 12, wherein the light sensing unit comprises a second wireless module.

18. The detecting system of claim 12, wherein the light-emitting device comprises a first wireless module.

19. The detecting system of claim 7, wherein the at least one light source comprises at least one light emitting diode.

20. The detecting system of claim 7, wherein the sampling frequency is greater than a predetermined frequency.

21. The detecting system of claim 20, wherein the median value is a sum of (1-k) times of a minimum sample value and k times of a maximum sample value, wherein 0<k <1.

22. The detecting system of claim 21, wherein the distance N is a distance between two numbers 1 or two numbers −1 in the second sequence.

23. The detecting system of claim 22, wherein the distance N between two numbers 1 in the second sequence has a first numeric value, the distance N between two numbers −1 in the second sequence has a second numeric value and the flickering frequency of the light source is between the sampling frequency divided by the first numeric value and the sampling frequency divided by the second numeric value.
